(19) United States
(12) Patent Application Publication
(10) Pub. No.: US 2013/0178001 A1
(43) Pub. Date: Jul. 11, 2013

(54) Method for Making LED LAMP

(71) Applicant: Wen-Lung Chin, New Taipei City (TW)

(72) Inventor: Wen-Lung Chin, New Taipei City (TW)

(21) Appl. No.: 13/344,678

(22) Filed: Jan. 6, 2012

(51) Int. Cl. H01L 33/52; B29C 45/16

(52) U.S. Cl. 438/26; 264/279; 257/E33.059

(57) ABSTRACT

A method for making an LED lamp includes a first step of working a base plate, a second step of placing the base plate in a die cavity of an injection molding machine, and a third step of forming a housing in the die cavity of the injection molding machine to combine the housing with the base plate. The base plate is integrally combined with the housing completely by injection molding so that the base plate and the housing are combined closely and solidly and will not detach from each other.

### BACKGROUND OF THE INVENTION

1. Field of the Invention

The present invention relates to a method for making a lighting appliance and, more particularly, to a method for making an LED (light emitting diode) lamp.

2. Description of the Related Art

A conventional LED (light emitting diode) lamp comprises a housing, and a base plate combined with the housing. The base plate is combined with an LED module (which is a modularized product) so that the base plate and the LED module are packed to function as an LED light source. Alternatively, the base plate is combined with at least one LED crystal so that the base plate and the LED crystal are packed to function as an LED light source. The base plate and the housing are made of two different materials. The base plate has a plurality of screw holes, and the housing has a plurality of screw bores which are connected with the screw holes of the base plate by a plurality of screw members (such as screws and the like) so that the base plate is combined with the housing by screwing. However, the base plate is not combined with the housing closely and tightly by screwing, thereby decreasing the structural strength of the LED lamp. Alternatively, the base plate is combined with the housing by a bonding agent, such as a gel and the like. However, the bonding agent is located between the base plate and the housing, thereby decreasing the heat conducting effect of the LED lamp.

### BRIEF SUMMARY OF THE INVENTION

In accordance with the present invention, there is provided a method for making an LED lamp, comprising a first step of working a base plate, a second step of placing the base plate in a die cavity of an injection molding machine, and a third step of forming a housing in the die cavity of the injection molding machine by injection molding to combine the housing with the base plate integrally.

Preferably, the first step of the method further includes providing at least one LED crystal on the base plate, and packing the base plate and the LED crystal to construct an LED light source.

Preferably, the first step of the method further includes providing an LED module on the base plate, and combining the base plate and the LED module to construct an LED light source.

Preferably, in the third step of the method, the housing surrounds the base plate so that the base plate is received in the housing.

Preferably, in the third step of the method, the housing is made of a plastic material and is combined with the base plate integrally by plastic injection molding.

Preferably, the base plate is made of a metal having great heat conductivity and great heat dissipation.

Preferably, the base plate is made of a porous nonmetallic material with great heat conduction and great heat dissipation.

Preferably, the housing is made of a porous nonmetallic material with great heat conduction and great heat dissipation.

Preferably, the base plate is made of a porous nonmetallic material with great heat conduction and great heat dissipation. The first step of the method further includes providing an LED module on the base plate, and combining the base plate and the LED module to construct an LED light source. The housing is made of a plastic material and is combined with the base plate integrally by plastic injection molding.

Preferably, the base plate is made of a porous nonmetallic material with great heat conduction and great heat dissipation. The first step of the method further includes providing at least one LED crystal on the base plate, and packing the base plate and the LED crystal to construct an LED light source. The housing is made of a plastic material and is combined with the base plate integrally by plastic injection molding.

Preferably, the base plate is made of a metal having great heat conductivity and great heat dissipation. The first step of the method further includes providing an LED module on the base plate, and combining the base plate and the LED module to construct an LED light source. The housing is made of a plastic material and is combined with the base plate integrally by plastic injection molding.

Preferably, the base plate is made of a metal having great heat conductivity and great heat dissipation. The first step of the method further includes providing at least one LED crystal on the base plate, and packing the base plate and the LED crystal to construct an LED light source. The housing is made of a plastic material and is combined with the base plate integrally by plastic injection molding.

Preferably, the base plate is made of a porous nonmetallic material with great heat conduction, the housing is made of a porous nonmetallic material with great dissipation, and the method for making the LED lamp further comprises a fourth step of treating the base plate and the housing by a sintering process.

The primary objective of the present invention is to provide a method for making an LED lamp which has an enhanced structural strength.

According to the primary advantage of the present invention, the base plate is integrally combined with the housing completely by injection molding so that the base plate and the housing are combined closely and solidly and will not detach from each other so as to enhance the structural strength of the LED lamp.

According to another advantage of the present invention, the base plate and the housing are combined closely so as to enhance the heat conducting effect of the LED lamp.

Further benefits and advantages of the present invention will become apparent after a careful reading of the detailed description with appropriate reference to the accompanying drawings.

### BRIEF DESCRIPTION OF THE SEVERAL VIEWS OF THE DRAWING(S)

FIG. 1 is a front cross-sectional assembly view of an LED lamp made by a method in accordance with the preferred embodiment of the present invention.

### DETAILED DESCRIPTION OF THE INVENTION

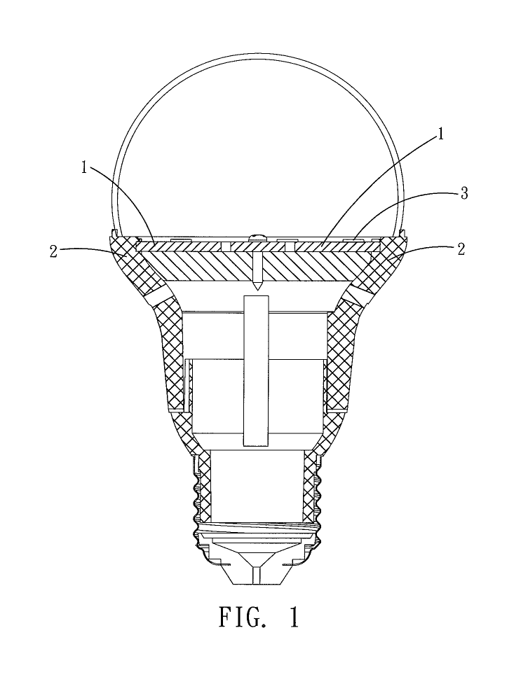

Referring to FIG. 1, an LED (light emitting diode) lamp in accordance with the preferred embodiment of the present invention comprises a housing 2, and a base plate 1 combined with the housing 2. The base plate 1 is integrally combined with the housing 2 by plastic injection molding. The base plate 1 is combined with an LED module (which is a modularized product) so that the base plate 1 and the LED module are packed to function as an LED light source. Alternatively, the base plate 1 is combined with at least one LED crystal 3 so that the base plate 1 and the LED crystal 3 are packed to function as an LED light source.

A method for making the LED lamp in accordance with the preferred embodiment of the present invention comprises a first step of working a base plate 1, a second step of placing the base plate 1 in a die cavity of an injection molding machine, and a third step of forming a housing 2 in the die cavity of the injection molding machine by injection molding to combine the housing 2 with the base plate 1 integrally.

The first step of the method further includes providing at least one LED crystal 3 on the base plate 1, and packing the base plate 1 and the LED crystal 3 to construct an LED light source. Alternatively, the first step of the method further includes providing an LED module on the base plate 1, and combining the base plate 1 and the LED module to construct an LED light source. In the first step of the method, the base plate 1 is flattened and drilled by working.

In the third step of the method, the housing 2 surrounds the base plate 1 so that the base plate 1 is received in the housing 2. In the third step of the method, the housing 2 is made of a plastic material and is combined with the base plate 1 integrally by plastic injection molding.

In the preferred embodiment of the present invention, the base plate 1 is made of a metal having great heat conductivity and great heat dissipation, such as gold, silver, copper, iron, aluminum, cobalt, nickel, zinc, titanium, manganese and the like. Alternatively, the base plate 1 is made of a porous nonmetallic material with great heat conduction and great heat dissipation. The porous nonmetallic material of the base plate 1 is made of a nonmetallic powder having a great heat conductivity, such as Al₂O₃, Zr₂O, AlN, SiN, BN, WC, SiC, C, crystalline SiC, Recrystalline SiC (ReSiC) and the like. Preferably, the nonmetallic powder of the base plate 1 is selected by AlN and SiC.

In the preferred embodiment of the present invention, the housing 2 is made of a plastic material. Alternatively, the housing 2 is made of a porous nonmetallic material with great heat conduction and great heat dissipation. The porous nonmetallic material of the housing 2 is made of a nonmetallic powder having a great heat conductivity, such as Al₂O₃, Zr₂O, AlN, SiN, BN, WC, SiC, C, crystalline SiC, Recrystalline SiC (ReSiC) and the like. Preferably, the nonmetallic powder of the base plate 1 is selected by AlN and SiC.

In the preferred embodiment of the present invention, the housing 2 has an end portion provided with a threaded stud for mounting a metallic screw base, an insulating gasket and a power contact plate. Preferably, each of the metallic screw base, the insulating gasket and the power contact plate has an international specification of E-27, E-14 and the like so that the housing 2 is available for a conventional electric bulb.

Alternatively, the housing 2 is provided with two connecting pins (with an international specification of MR16 and the like) so that the housing 2 is available for a conventional projection lamp.

In the preferred embodiment of the present invention, the base plate 1 is made of a porous nonmetallic material with great heat conduction, the housing 2 is made of a porous nonmetallic material with great dissipation, and the method for making the LED lamp further comprises a fourth step of treating the base plate 1 and the housing 2 by a sintering process.

Accordingly, the base plate 1 is integrally combined with the housing 2 completely by injection molding so that the base plate 1 and the housing 2 are combined closely and solidly and will not detach from each other so as to enhance the structural strength of the LED lamp. In addition, the base plate 1 and the housing 2 are combined closely so as to enhance the heat conducting effect of the LED lamp.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

1. A method for making an LED lamp, comprising:
a first step of working a base plate;
a second step of placing the base plate in a die cavity of an injection molding machine; and
a third step of forming a housing in the die cavity of the injection molding machine by injection molding to combine the housing with the base plate integrally.

2. The method of claim 1, wherein the first step of the method further includes:
providing at least one LED crystal on the base plate; and
packing the base plate and the LED crystal to construct an LED light source.

3. The method of claim 1, wherein the first step of the method further includes:
providing an LED module on the base plate; and
combining the base plate and the LED module to construct an LED light source.

4. The method of claim 1, wherein in the third step of the method, the housing surrounds the base plate so that the base plate is received in the housing.

5. The method of claim 1, wherein in the third step of the method, the housing is made of a plastic material and is combined with the base plate integrally by plastic injection molding.

6. The method of claim 1, wherein the base plate is made of a metal having great heat conductivity and great heat dissipation.

7. The method of claim 1, wherein the base plate is made of a porous nonmetallic material with great heat conduction and great heat dissipation.

8. The method of claim 1, wherein the housing is made of a porous nonmetallic material with great heat conduction and great heat dissipation.

9. The method of claim 1, wherein
the base plate is made of a porous nonmetallic material with great heat conduction and great heat dissipation;
the first step of the method further includes:
providing an LED module on the base plate; and
combining the base plate and the LED module to construct an LED light source;
the housing is made of a plastic material and is combined with the base plate integrally by plastic injection molding.

10. The method of claim 1, wherein
the base plate is made of a porous nonmetallic material with great heat conduction and great heat dissipation;
the first step of the method further includes:
providing at least one LED crystal on the base plate; and
packing the base plate and the LED crystal to construct an LED light source;
the housing is made of a plastic material and is combined with the base plate integrally by plastic injection molding.

11. The method of claim 1, wherein
the base plate is made of a metal having great heat conductivity and great heat dissipation;
the first step of the method further includes:
providing an LED module on the base plate; and
combining the base plate and the LED module to construct an LED light source;
the housing is made of a plastic material and is combined with the base plate integrally by plastic injection molding.

12. The method of claim 1, wherein
the base plate is made of a metal having great heat conductivity and great heat dissipation;
the first step of the method further includes:
providing at least one LED crystal on the base plate; and
packing the base plate and the LED crystal to construct an LED light source;
the housing is made of a plastic material and is combined with the base plate integrally by plastic injection molding.

13. The method of claim 1, wherein
the base plate is made of a porous nonmetallic material with great heat conduction;
the housing is made of a porous nonmetallic material with great dissipation;
the method for making the LED lamp further comprises a fourth step of treating the base plate and the housing by a sintering process.
